(19) United States
(12) Patent Application Publication
(10) Pub. No.: US 2009/0261329 A1
(43) Pub. Date: Oct. 22, 2009

(54) DISPLAY DEVICE

(76) Inventors: Ichiro YAMAKAWA, Fujisawa (JP); Kazuhiko Horikoshi, Yokohama (JP); Yoshiki Yonamoto, Yokohama (JP); Naotoshi Akamatsu, Fujisawa (JP); Toshihiko Itoga, Chiba (JP); Takuo Kaitoh, Mobara (JP); Takahiro Kamo, Tokyo (JP); Gi-il Kim, Tokyo (JP); Takeshi Sakai, Kokubunji (JP); Noboru Ooki, Ooamishirasato (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/423,865

(22) Filed: Apr. 15, 2009

(30) Foreign Application Priority Data
Apr. 17, 2008 (JP) 2008-107442

(51) Int. Cl. H01L 33/00; H01L 29/786

(52) U.S. Cl. 257/57; 257/E33.053; 257/E29.291

(57) ABSTRACT

Provided is a display device using a TFT serving as a switching element, in which image deterioration of the display device is prevented by suppressing a photo leakage current to be small, and in particular, in which a density of defects which become positive fixed charges by light present in a protective insulating film of the TFT is defined to suppress the photo leakage current. In the display device using the TFT, the TFT includes an insulating film, an amorphous silicon film, a drain electrode and a source electrode, and a protective insulating film laminated on a gate electrode covering a part of a surface of an insulating substrate in the stated order, in which the protective insulating film includes a defect which becomes a positive fixed charge under light irradiation. A surface density of the defects is preferably 2.5×10¹⁰ cm⁻² or more to 4.0×10¹⁰ cm⁻² or less.

### CROSS-REFERENCE TO RELATED APPLICATION

The present application claims priority from Japanese application JP 2008-107442 filed on Apr. 17, 2008, the content of which is hereby incorporated by reference into this application.

### BACKGROUND OF THE INVENTION

1. Field of the Invention

The present invention relates to a display device including a thin film transistor (hereinafter, referred to as TFT) serving as a switching element, and more particularly, to a display device including an active matrix display portion.

2. Description of the Related Art

A TFT used as a switching element in a display device according to a related art is formed as follows. For example, as illustrated in FIGS. 13A to 13C, metal is patterned in a desired shape on a glass substrate 1 which is an insulating substrate to form a gate electrode 2. On the gate electrode 2, an insulating film 3, an amorphous silicon (hereinafter, referred to as a-Si) film 4, and a heavily-doped a-Si film 5 are continuously formed. The heavily-doped a-Si film 5 and the a-Si film 4 are simultaneously patterned so as to have an island-like structure. After that, a metal film 6 is formed and patterned to form a source electrode 7 and a drain electrode 8. Further, in a region between the source electrode 7 and the drain electrode 8, the heavily-doped a-Si film 5 is removed by dry etching or the like, and the a-Si film 4 is exposed. Then, a silicon nitride (SiN) protective film 9 is formed on the entire surface of the substrate, to thereby form a TFT (see JP 2003-37270 A, for example).

### SUMMARY OF THE INVENTION

The TFT according to the related art has a feature of a large drain current (photo leakage current) which is obtained in an off state under light irradiation because a photoconductivity of the a-Si film is high.

Particularly, in recent years, liquid crystal displays are required to attain high brightness and make an external lighting such as a backlight have higher brightness. With the backlight of higher brightness, a larger amount of light emitted from the backlight enters by reflection, diffraction, or the like in the device through the a-Si film of the TFT. As a result, a photo leakage current is generated in the TFT and there arises a problem that display characteristics of the liquid crystal display is deteriorated.

One way of reducing the photo leakage current is, for example, to provide a light shielding structure so that a TFT region is not irradiated with light emitted from a backlight. However, with this light shielding structure, an aperture ratio of a panel is reduced and there arises another problem that brightness of the liquid crystal displays is reduced.

The photo leakage current is caused by, for example, electrons excited by light in the a-Si film. When electrons which are present in the valence band of a-Si are excited by light, the electrons have conductivity. Particularly, when the TFT is in the off state, that is, when a bias voltage of a gate electrode is negative, an electric field generated from the gate electrode moves the electrons excited by the light in the a-Si film to a side end surface of the a-Si film adjacent to the SiN protective film. Those electrons form a channel (back channel) between a source and a drain, which causes the photo leakage current. In this case, the amount of a current flowing through the back channel depends on the density of electrons excited by light in the a-Si film, and on the lifetime of electrons excited by light. Those factors result from a film quality in the a-Si film, such as a defect density.

In order to reduce the photo leakage current generated by such a mechanism, in JP 06-252404 A, for example, defects are formed so as to have a defect density of 1×10¹⁷ cm⁻³ or more on a surface of the a-Si film on the back channel side (Related Art 1).

Further, in JP 2003-297749 A, there is formed, as an active layer, a silicon film formed of continuous grain boundary crystals, in which microcrystals such as polysilicon containing a large number of carrier traps are distributed (Related Art 2).

Further, in JP 2003-37270 A, in the manufacturing steps for the TFT, between the step of performing channel etching and the step of forming a passivation insulating film, oxygen plasma treatment as the first plasma treatment is performed and then hydrogen plasma treatment as the second plasma treatment is performed, whereby the surface layer of the a-Si film is inactivated up to a region to which oxygen atoms cannot penetrate.

Further, in JP 10-214972 A, in the manufacturing steps for the TFT, an oxide film which is formed in the oxygen plasma step of terminating the dangling bond in the polysilicon layer which becomes an active layer is removed before a gate insulating film is formed. Through this step, thresholds of the TFT are prevented from shifting to a negative voltage or being unstable due to charges mixed in the oxygen plasma step. In addition, a leakage current generated in the back channel portion, which results from the charges taken into the oxide film, is suppressed.

The inventor has studied the cause of the photo leakage current of the TFT to find that positive charges (positive fixed charges) are induced in the SiN protective film of the TFT under light irradiation. Besides, the inventor has found that positive fixed charges induced by the light irradiation are attributed to the defects in the SiN protective film.

The positive fixed charges that appear in the SiN protective film by the light irradiation reinforce an electric field generated from the gate electrode, and thus the back channel formation is promoted, to thereby work so as to increase an off current. Accordingly, an increase of the defect density in the SiN protective film becomes a factor that increases the photo leakage current. On the other hand, among the defects in the SiN protective film, the defect which is present in the vicinity of the interface with the a-Si film works as recombination center of electrons excited by light. When the density of the defects is extremely reduced, the lifetime of the electrons flowing through the back channel is increased. Accordingly, the excessive decrease of the defect density in the SiN protective film becomes a factor that increases the photo leakage current.

Relates Arts 1 and 2 (JP 06-252404 A and JP 2003-297749 A) are made to control the density of the electrons excited by the light in the silicon film, and cannot be applied to the control of the photo leakage current resulting from the positive charges that appear in the SiN protective film.

The relation between the photo leakage current and the density of the defects which become the positive fixed charges by light in the SiN protective film is not generally known. On the other hand, in the TFT of the liquid crystal display, in a general operation voltage at the time of an off operation, a gate voltage is −7 to −10 V, and a drain voltage is 10 V. In order to obtain an excellent image, the photo leakage current at the time of the off operation is preferably 1×10⁻¹¹ A or less.

An object to be achieved by the present invention is, in a display device provided with a TFT serving as a switching element, to improve an image quality of the display device by suppressing a photo leakage current, and in particular, to define to what extent a density of defects which become positive fixed charges under light irradiation in an SiN protective film has to be reduced, and to suppress the photo leakage current to be 1×10⁻¹¹ A or less.

In order to achieve the above-mentioned object, the present invention provides a display device including: a gate electrode formed on a surface of an insulating substrate; an a-Si film formed on the gate electrode through an insulating film; a drain electrode and a source electrode formed on the a-Si film; and a protective insulating film, in which the protective insulating film contains a defect which becomes a positive fixed charge by light irradiation.

A surface density of the defects which become positive fixed charges by light irradiation is preferably from 2.5×10¹⁰ cm⁻² or more to 4.0×10¹⁰ cm⁻² or less. With such a structure, the surface density of the positive fixed charges induced in the protective insulating film under light irradiation can be suppressed to 4.0×10¹⁰ cm⁻² or less. Accordingly, the back channel formation by the positive charges in the protective insulating film can be prevented from being promoted. Further, among the defects described above, the defect in the vicinity of the interface between the a-Si film and the protective insulating film works as the recombination center of photocarriers, and hence the surface density of the defects is at least 2.5×10¹⁰ cm⁻² or more, which can suppress the increase of the photocarriers under the light irradiation.

The display device achieved by the present invention has the effect of improving the image quality of the display device by suppressing the photo leakage current.

### BRIEF DESCRIPTION OF THE DRAWINGS

In the accompanying drawings:

FIG. 1 is a sectional view of a liquid crystal display device according to embodiments of the present invention;

FIG. 2 is a schematic view of a TFT array according to the embodiments of the present invention;

FIG. 3 is a sectional view illustrating a part of the TFT array according to the embodiments of the present invention;

FIGS. 4A to 4C are sectional views illustrating a manufacturing method in an order of steps according to a first embodiment of the present invention;

FIGS. 5A to 5D are sectional views illustrating a manufacturing method for a sample for measuring a surface density of defects which become positive fixed charges under light irradiation;

FIG. 6 is a schematic view of a case where a TFT according to the first embodiment of the present invention is set in a thermally stimulated current measuring device for measuring a density of the defects which become the positive fixed charges under the light irradiation;

FIG. 7 is a graph illustrating a relation between a defect density of states and a defect energy level thereof in the first embodiment of the present invention;

FIGS. 8A to 8C are each energy band diagrams for illustrating defect energy levels in which positive charges are generated under light irradiation in the present invention;

FIG. 9 is a graph illustrating a relation between the surface density of the defects which become the positive fixed charges under the light irradiation and a photo leakage current in the first embodiment of the present invention;

FIGS. 10A and 10B are sectional views illustrating a manufacturing method in an order of steps according to a second embodiment of the present invention;

FIG. 11 is a graph illustrating a depth distribution of an oxygen atom density in the second embodiment of the present invention;

FIG. 12 is a graph illustrating a relation between an oxygen plasma treatment time and a photo leakage current in the second embodiment of the present invention; and

FIGS. 13A to 13C are sectional views illustrating a part of a TFT in a conventional liquid crystal display device.

### DETAILED DESCRIPTION OF THE INVENTION

Hereinafter, embodiments of the present invention are described in detail with reference to the drawings. Hereinbelow, embodiments of a liquid crystal display device are described. Here, the liquid crystal display device may be an in-plane switching (IPS) liquid crystal display device, or other liquid crystal display devices such as a vertically-aligned (VA) liquid crystal display device and a twisted nematic (TN) liquid crystal display device. Moreover, the liquid crystal display device may be another display device such as an organic electroluminescent (EL) display device as long as the TFT is provided as a switching element.

### First Embodiment

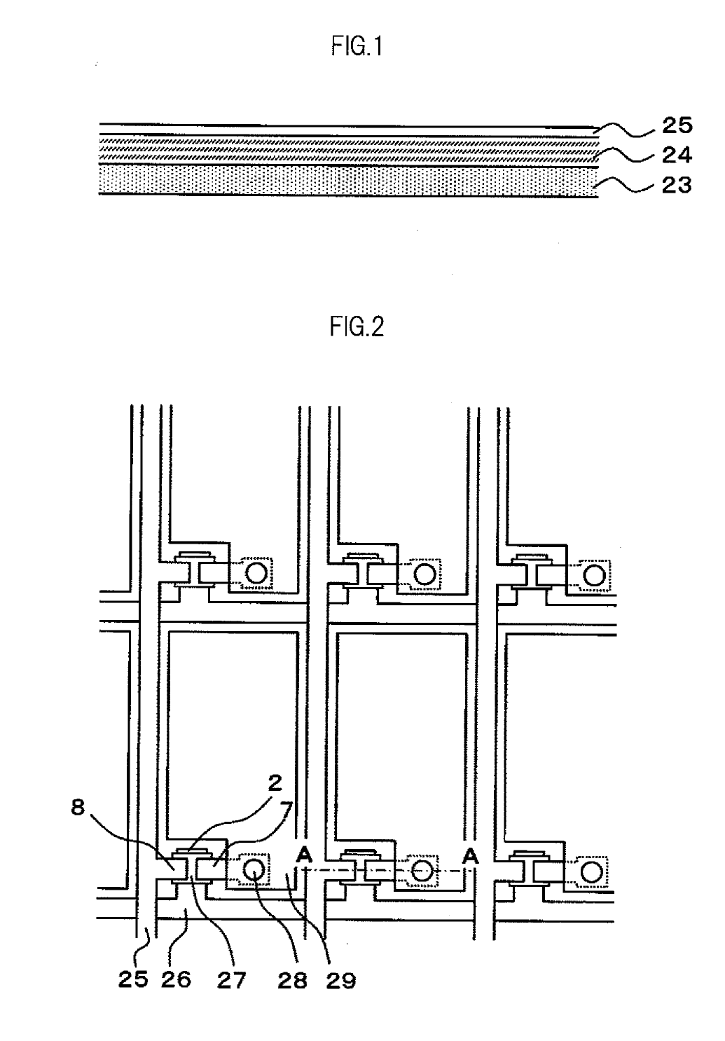

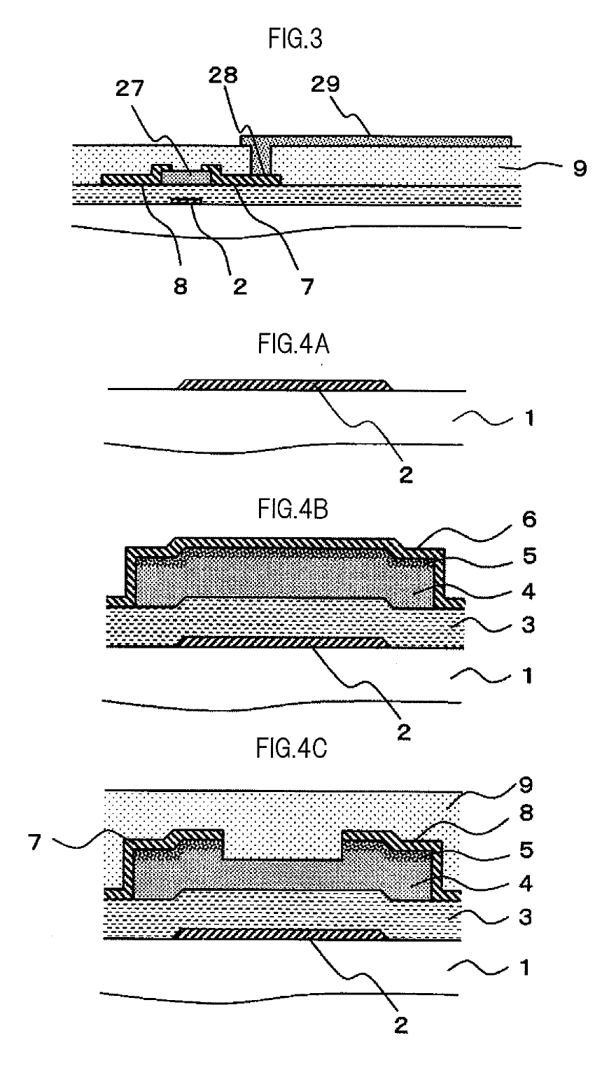

Referring to FIGS. 1 to 3 and FIGS. 4A to 4C, a first embodiment of the present invention is described. FIG. 1 is a view schematically illustrating a cross-sectional structure of a liquid crystal display device according to this embodiment. FIG. 2 is a view schematically illustrating a structure of a thin film transistor (TFT) array of the liquid crystal display device. FIG. 3 is a sectional view taken along the line segment AA of FIG. 2. FIGS. 4A to 4C are sectional views schematically illustrating a part of a manufacturing method for a TFT according to this embodiment.

As illustrated in FIG. 1, the liquid crystal display device according to this embodiment includes a TFT array substrate 23 including the TFT array serving as a switching element, an opposed substrate 25 which is opposed to the TFT array substrate 23, and a liquid crystal layer 24 interposed between the TFT array substrate 23 and the opposed substrate 25. As illustrated in FIG. 2, the TFT array is formed by arranging a plurality of drain lines 25, a plurality of gate lines 26, a plurality of TFTs 27, a plurality of pixel electrodes 29, and a plurality of source electrodes 7. In the TFT 27, a part of the drain line 25 becomes a drain electrode 8, and a part of the gate line 26 becomes a gate electrode 2. Further, as illustrated in FIG. 3, the pixel electrode 29 formed on a protective insulating film 9 is connected to the source electrode 7 through a contact hole 28.

Hereinbelow, a manufacturing method for the TFT array and the features of the TFT are described. First, as illustrated in FIG. 4A, a metal film is formed by sputtering on a glass substrate 1 which is an insulating substrate, and is patterned to form the gate electrode 2. As illustrated in FIG. 2, the gate electrode 2 is a part of the gate line 26, and therefore the gate electrode 2 and the gate line 26 are formed simultaneously. The material of the gate electrode 2 is preferably metal containing aluminum or molybdenum. Then, as illustrated in FIG. 4B, on a surface of the glass substrate 1 on which the gate electrode 2 is formed, an insulating film 3, an amorphous silicon (a-Si) film 4, and a heavily-doped a-Si film 5 are continuously formed by plasma CVD. After that, the heavily-doped a-Si film 5 and the a-Si film 4 are subjected to photo etching to be formed into an island-like shape at the same time. Here, the insulating film 3 is preferably a silicon nitride (SiN) film made from monosilane and ammonia as raw materials, the a-Si film 4 is preferably a film made from monosilane and hydrogen as raw materials, and the heavily-doped a-Si film 5 is preferably an n-type a-Si film made from monosilane, hydrogen, and phosphine as raw materials. After that, a metal film 6 is formed by sputtering. As illustrated in FIG. 4C, the formed metal film 6 is patterned by photo etching to form the source electrode 7, the drain electrode 8, and the drain line 25 illustrated in FIG. 2. The metal film 6 is preferably an alloy containing molybdenum and tungsten. In addition, the heavily-doped a-Si film 5 in a region between the source electrode 7 and the drain electrode 8 is removed by dry etching to expose the a-Si film 4. The dry etching is preferably dry etching using plasma of a mixed gas containing sulfur hexafluoride and oxygen. In the dry etching, a part of the a-Si film 4 may be etched. Further, oxygen plasma treatment in which annealing is performed under microwave-excited oxygen plasma is performed on the surface of the glass substrate 1. On the surface of the glass substrate 1, an SiN protective insulating film 9 is further formed by plasma CVD to form a TFT. The SiN protective insulating film 9 is preferably an SiN film made from monosilane and ammonia as raw materials and formed at a temperature of 320° C. Then, as illustrated in FIG. 3, a contact hole is provided in a part of the SiN protective insulating film 9 so as to expose a part of the source electrode 7. Finally, in a case of a transmissive liquid crystal display device, a transparent electrode formed of indium tin oxide or the like is formed in a pixel portion as the pixel electrode 29. On the other hand, in a case of a reflective liquid crystal display device, a reflective electrode formed of aluminum or the like is formed in the pixel portion as the pixel electrode 29. After that, the pixel electrode 29 is connected to the source electrode 7 through the contact hole 28, to thereby form the TFT array substrate 23.

The inventor has studied the cause of a photo leakage current of the TFT in the TFT array substrate 23 thus formed, and has found that a positive charge is induced under light irradiation in the SiN protective insulating film 9 of the TFT. In addition, the inventor has found that a positive fixed charge induced by the light irradiation results from a defect in the SiN protective insulating film 9 as follows.

First, a method of evaluating a surface density of defects which become positively charges under the light irradiation is described. One method of measuring the surface density of the defects in a thin film formed of a semiconductor or an insulator is a thermally stimulated current (TSC) method. This method is known as a technique of obtaining a defect energy level and a surface density thereof accurately (Dielectrics and Electrical Insulation, IEEE Transactions on, Volume 6, pp. 852 to 857 (1999)). Hereinbelow, the TSC method is described. A semiconductor thin film sample is interposed between two metal materials, and a voltage is applied to the two metal materials to cause a current to flow. In this case, a phenomenon in which electrons are captured in a defect energy level of the semiconductor thin film occurs. The sample is cooled to a low temperature with the voltage being applied thereto and thereafter the voltage application is stopped. The temperature of the sample is increased at a constant rate. In the meanwhile, a current flowing through the sample and a temperature of the sample are continuously measured. When a current value thus measured is larger, the surface density of the defects in the semiconductor thin film becomes larger, and when the observation is made at a higher temperature, the defect energy level is deeper.

A method of measuring a surface density of defects which become positive fixed charges under light irradiation in the TFT provided in the liquid crystal display device according to this embodiment is described below.

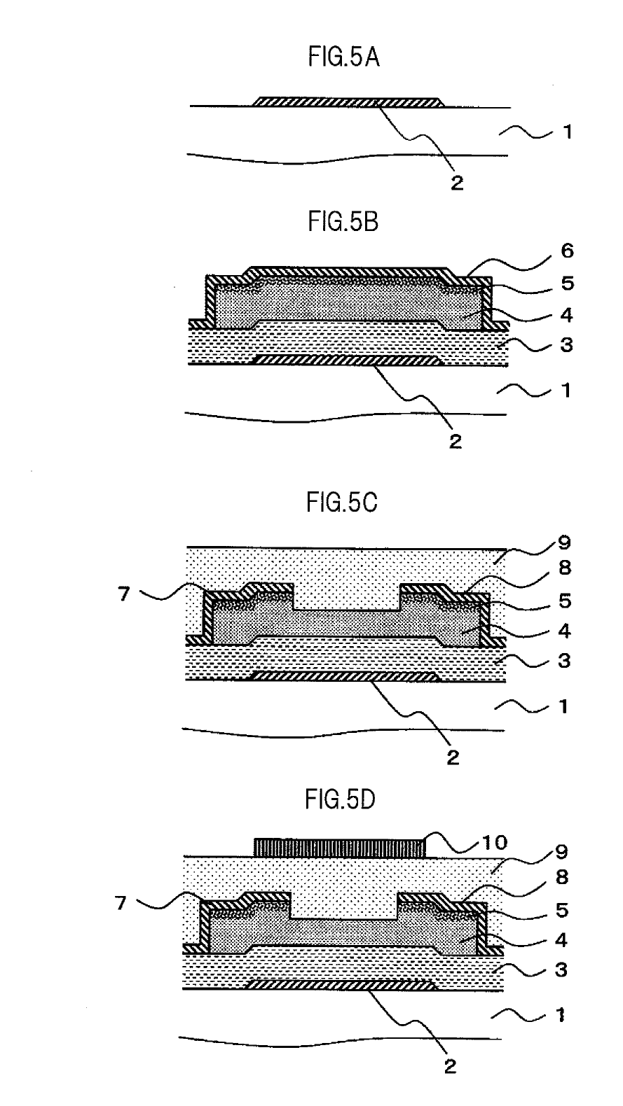

FIGS. 5A to 5D are views illustrating a manufacturing method for a sample for measuring a surface density of defects which become positive fixed charges under light irradiation. FIGS. 5A to 5C are the same as FIGS. 4A to 4C described above, and the steps so far are the same as those of a manufacturing method for a general TFT array substrate. Here, with respect to some TFTs, as illustrated in FIG. 5D, an upper electrode 10 is formed on the surface of the TFT manufactured by the above-mentioned method. The upper electrode 10 is formed by using a conductive paste material above the interface between the a-Si film 4 and the SiN protective insulating film 9, the interface being in the region between the source electrode 7 and the drain electrode 8. In this embodiment, the conductive paste material is used as the material of the upper electrode 10, but other materials may be used. For example, indium tin oxide formed by sputtering may be used. In a measurement described below, light is used for irradiation. Even when the upper electrode 10 is opaque, light enters from ends of the upper electrode 10, and therefore the upper electrode 10 may be opaque. As the matter of course, the upper electrode 10 may be a transparent electrode.

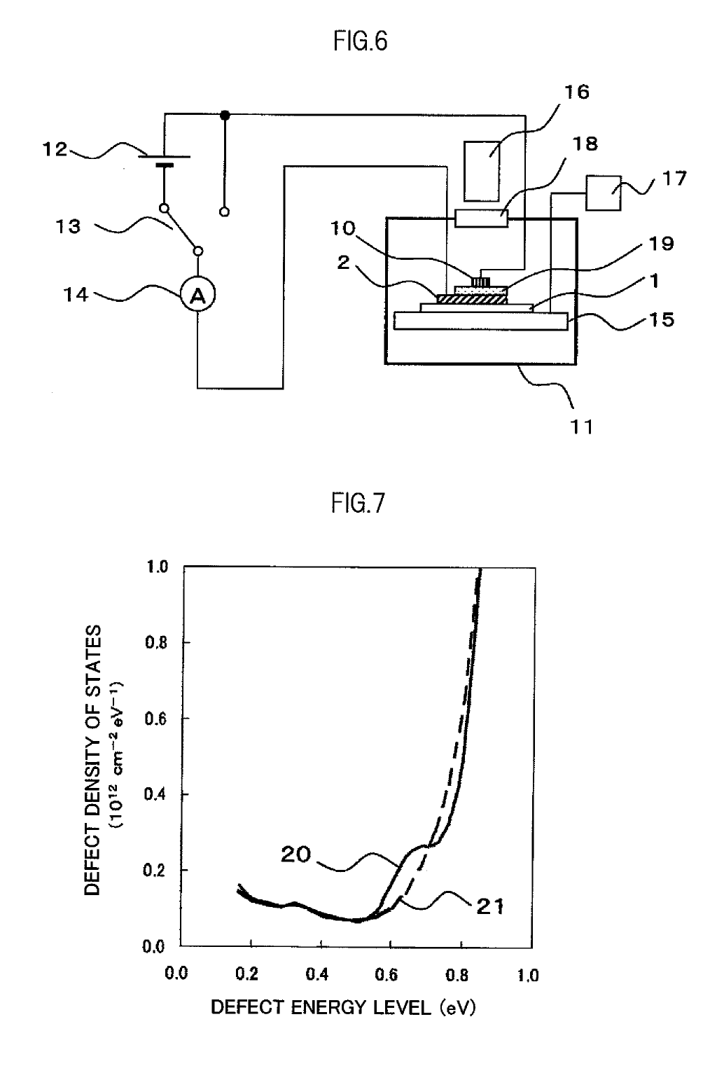

For the TFT on which the upper electrode 10 illustrated in FIG. 5D is formed, a measurement by the TSC method is performed by using the upper electrode 10 and the gate electrode 2. For the measurement, as illustrated in FIG. 6, a constant voltage DC power supply 12, a switch 13, and an ammeter 14 are connected between the upper electrode 10 and the gate electrode 2. Further, the glass substrate 1 on which the TFTs are formed is placed on a temperature adjustment stage 15. The temperature adjustment stage 15 is necessary to be capable of adjusting the temperature at least from −190° C. to 250° C. A white light source 16 is used to irradiate the TFT with light. For the white light source 16, there is used a light source which outputs light having a continuous spectrum in a wavelength within the range at least from 400 nm to 800 nm. Such a light source includes, for example, a tungsten lamp and a metal halide lamp.

The measurement is conducted by the following procedure. First, the temperature adjustment stage 15 is used to heat the sample to 250° C. The switch 13 is connected to the constant voltage DC power supply 12 while the temperature is maintained, and a DC voltage is applied between the upper electrode 10 and the gate electrode 2. The DC voltage is, for example, 80 V. When the temperature and the voltage are kept constant, an amount of a flowing current is decreased with time. Accordingly, the temperature and the voltage are maintained until a current value becomes constant. Meanwhile, the insulating film captures charges. After that, the temperature of the sample is lowered to −190° C. with the voltage maintained, and then the switch 13 is flipped to stop the application of the DC voltage.

Subsequently, the white light source 16 is lighted, and the glass substrate 1 is irradiated with the light having the continuous spectrum from 400 nm to 800 nm. The temperature is raised at a constant rate with the glass substrate 1 being irradiated with the light, and a current flowing through the TFT and a temperature of the TFT are continuously measured with the use of a thermometer 17 and the ammeter 14 (in a case of Comparative Examples, a measurement is performed in a dark condition without lighting the white light source 16). In this case, the rate of the temperature rise is preferably 20° C. per minute. When the defect energy level and the thermal energy are equal to each other, the captured electrons are released to be observed as a current. The number of captured electrons is proportional to the defect density of states. Accordingly, the measured temperature and current value correspond to the defect energy level and the defect density of states, respectively.

In order to obtain an energy Eₜ of the defect energy level from a temperature T, the following Expression 1 is used.

(Expression 1)

Eₜ=kT ln(T⁴/β) (1)

In this expression, k represents the Boltzmann constant, and β represents a rate of a temperature rise.

Further, in order to obtain a defect density of states nₜ from a current value I, the following Expression 2 is used.

(Expression 2)

nₜ=(αI)/(qA) (2)

In this expression, α represents a time necessary to increase thermal energy by a unit quantity during a measurement by the TSC method, q represents an elementary charge, and A represents an electrode area. The value of α can be obtained by using time dependence of the temperature T and Expression 1.

A surface density Nₜ of defects is obtained by energy integral of the defect density of states nₜ as shown in Expression 3.

(Expression 3)

Nₜ=∫nₜdE (3)

FIG. 7 is a graph illustrating a relation between the defect energy level and the defect density of states, which are calculated from Expressions 1 and 2, based on measurement results of the ammeter 14 and the thermometer 17. A curve 20 shows a case where light is applied with the use of the white light source 16, and a curve 21 shows a case of a dark condition. In the vicinity of 0.65 eV of the characteristics shown by those curves, the curve 20 under the light irradiation has a peak, whereas the curve 21 under the dark condition has no peak.

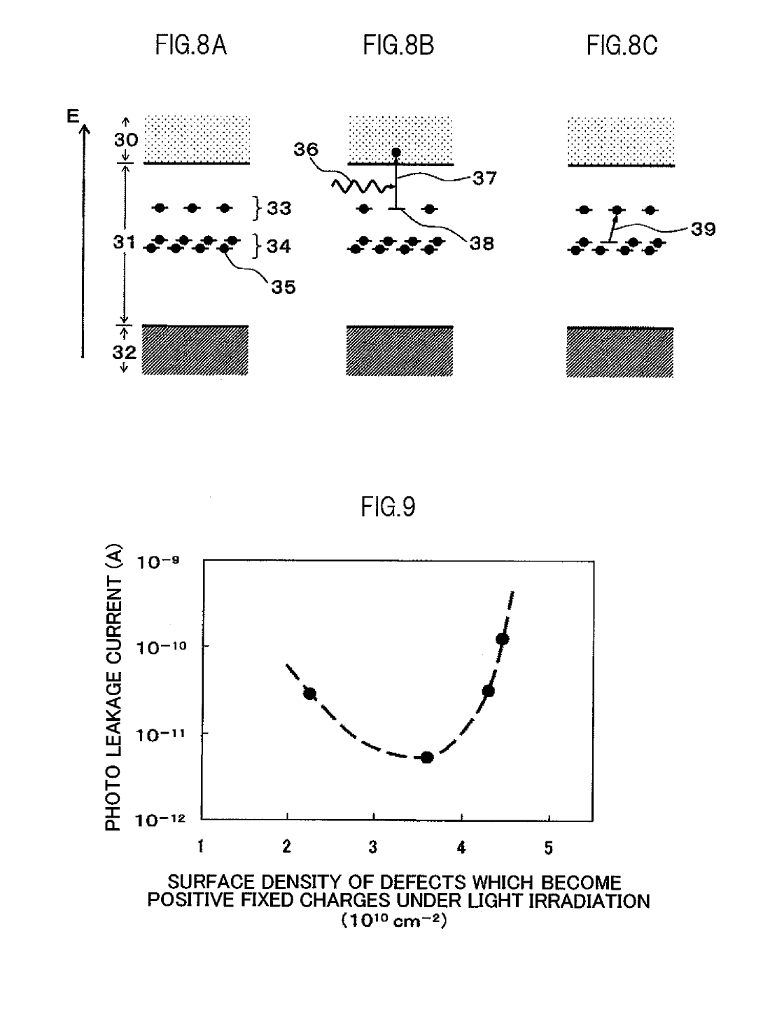

This peak is attributed to the defect energy level which becomes a positive fixed charge by light irradiation. The reason is described with reference to FIGS. 8A to 8C. FIGS. 8A to 8C are diagrams schematically illustrating an electron state and a defect energy level of SiN as an energy band diagram.

The electron state of SiN includes a valence band 32, a conduction band 30, and a forbidden band 31 which is an energy region therebetween. In the forbidden band 31, a defect energy level resulting from defects or impurities in the SiN is present. The defect energy level includes a defect energy level 34 located substantially in the center of the forbidden band 31 and having a high density, and a defect energy level 33 having energy higher than that of the defect energy level 34 by 0.65 eV. The defect energy level 33 becomes neutral when electrons are captured, and becomes positively charged when the electrons are released. As illustrated in FIG. 8A, the defect energy level 33 is neutral because the electrons have been captured. When the SiN is irradiated with light, the electrons captured by the defect energy level 33 receive energy from incident light 36 as illustrated in FIG. 8B. As a result, photoexcitation 37 occurs toward the conduction band 30, and excited electrons are detected as a current. A defect energy level 38 from which an electron escapes becomes positively charged and becomes a positive fixed charge in the SiN. When electrons captured in the defect energy level 34 receive thermal energy, as illustrated in FIG. 8C, electrons are captured in the defect energy level 33 due to thermal excitation 39, and accordingly a defect energy level is returned to be neutral. After that, a hole level generated in the defect energy level 34 is occupied by accepting an electron moving owing to a mechanism such as hopping conduction between the defect energy levels 34. In the above-mentioned TSC measurement, the photoexcitation 37 does not occur in the case of the dark condition, and hence a current attributed to the defect energy level 33 is not detected. On the other hand, in the above-mentioned TSC measurement, under light irradiation, thermal energy is increased by the temperature rise of the sample, and thermal excitation and photoexcitation occur simultaneously at a time when the thermal energy is equal to an energy difference between the defect energy level 33 and the defect energy level 34. Hence, electrons are excited toward the conduction band 30, whereby a current is detected. The current value detected at that time depends on a surface density of the defect energy level 33, and accordingly the surface density of the defect energy level 33 can be calculated.

The surface density of the defect energy level 33 is obtained by integrating the difference between the curve 20 and the curve 21 of FIG. 7 within the range from 0.55 eV to 0.75 eV.

FIG. 9 shows a relation between a photo leakage current and a surface density of defects which correspond to the defect energy level 33, that is, become positive fixed charges under light irradiation. In FIG. 9, the abscissa axis shows a surface density of defects which become positive fixed charges under light irradiation, in which the surface density has been obtained by the above-mentioned TSC measurement, and the ordinate axis shows a photo leakage current obtained by performing measurement on a TFT which does not include the upper electrode 10 in the same TFT array having the TFT including the upper electrode 10 which is subjected to the TSC measurement. FIG. 9 shows four measurement points which are measurement results on four samples. The four samples are different from each other in treatment time required for the oxygen plasma treatment in which annealing is performed under microwave-excited oxygen plasma in the steps illustrated in FIGS. 4C and 5C.

The photo leakage current of FIG. 9 represents a drain current value at a gate voltage of −7 V of the transistor under the light irradiation. Along with a decrease of the surface density of the defects from 4.5×10¹⁰ cm⁻² to 3.6×10¹⁰ cm⁻², positive charges captured in the SiN protective insulating film 9 are decreased, and hence the photo leakage current is decreased. On the other hand, when the surface density of the defects is decreased from 3.6×10¹⁰ cm⁻² to 2.3×10¹⁰ cm⁻², the photo leakage current is increased. This is because, among the defects which become positive fixed charges under light irradiation, defects which are present in the vicinity of the interface with the a-Si film 4 works as the recombination center of photocarriers, and the recombination center is decreased together with the decrease of the defect density to make longer the lifetime of the electrons in the back channel. When the surface density of the defects obtained when the photo leakage current is 1×10⁻¹¹ A is obtained by interpolating the plots of FIG. 9, the surface density of the defects is 2.5×10¹⁰ cm⁻² and 4.0×10¹⁰ cm⁻². Specifically, it is preferable to form the upper electrode 10 on the SiN protective insulating film 9, and to set a surface density of defects obtained by measuring a thermally stimulated current in a case where a TFT is irradiated with white light to be 2.5×10¹⁰ cm⁻² or more and 4.0×10¹⁰ cm⁻² or less.

As described above, when the surface density of the defects which become positive fixed charges under the light irradiation in the SiN protective insulating film 9 is within the range from 2.5×10¹⁰ cm⁻² to 4.0×10 cm⁻², the photo leakage current is 1×10⁻¹¹ A or less, which reveals that excellent transistor characteristics are obtained.

In the measurement described above, light is applied from the white light source 16 in the TSC measurement illustrated in FIG. 6, and the photoexcitation 37 is provoked as illustrated in FIG. 8B. In the actual TFT array substrate 23, the photoexcitation 37 illustrated in FIG. 8B occurs by backlight or external light. Specifically, in a liquid crystal display device formed of TFTs each including an insulating film, an amorphous silicon film, a drain electrode, a source electrode, and a protective insulating film laminated in the stated order on a gate electrode formed on apart of a surface of an insulating substrate, positive fixed charges (defect energy level 38 from which electrons escape) are generated by backlight or external light, whereby a photo leakage current is suppressed. Under the light irradiation, a surface density of the defect energy level 33 which become positive fixed charges is preferably set between 2.5×10¹⁰ cm⁻² and 4.0×10¹⁰ cm⁻².

Eventually, the TFT of this embodiment includes two defect energy levels 33 and 34 in the protective insulating film, the defect energy levels 33 and 34 having different energy levels by 0.65 eV. Of the two defect energy levels 33 and 34, the defect energy level 33 having a higher energy level is a defect which becomes a positive fixed charge under light irradiation. The defect having the higher energy level becomes electrically neutral when electrons are captured, and becomes positively charged when the electrons are released. Then, the electrons captured by the defect are released by the photoexcitation, whereby the defect becomes a positive fixed charge under the light irradiation.

### Second Embodiment

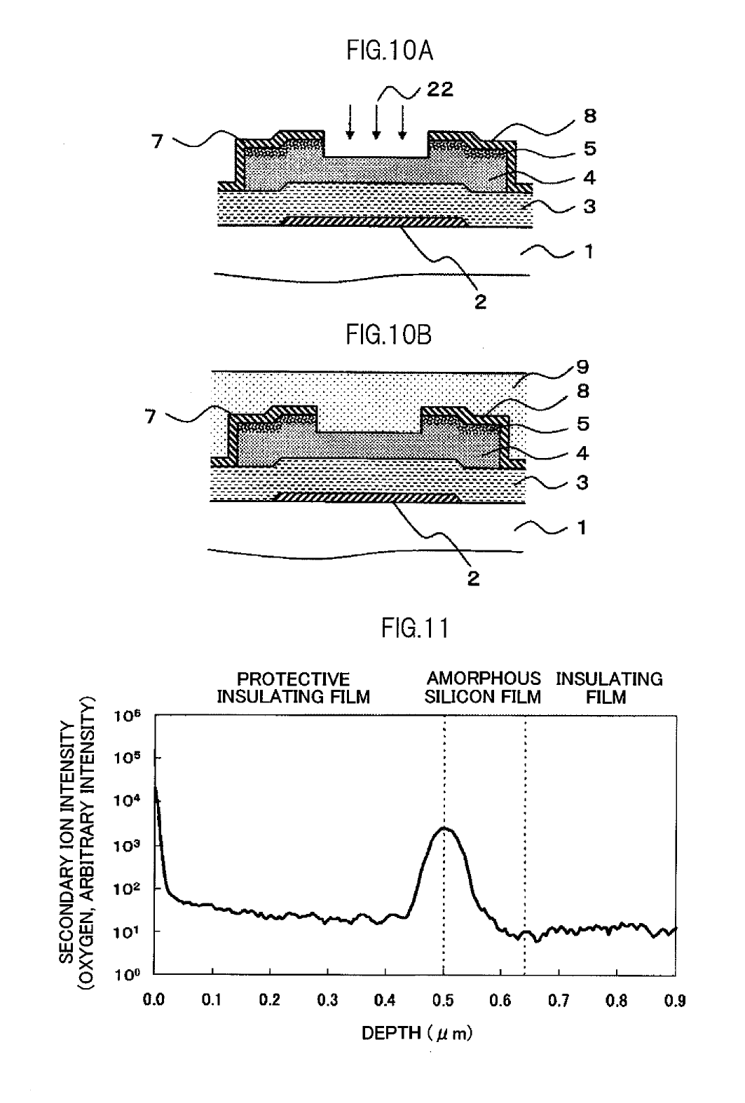

In a second embodiment of the present invention, a relation between an oxygen plasma treatment time and a photo leakage current is investigated. The second embodiment of the present invention is described with reference to FIGS. 10A and 10B. In this embodiment, through the steps similar to those of the first embodiment, the gate electrode 2, the insulating film 3, the a-Si film 4, the heavily-doped a-Si film 5, the source electrode 7, and the drain electrode 8 are formed, and the heavily-doped a-Si film 5 formed in a region between the source electrode 7 and the drain electrode 8 is removed by dry etching to expose the a-Si film 4. In addition, oxygen plasma treatment 22 in which annealing is performed under microwave-excited oxygen plasma is performed. As conditions for the oxygen plasma treatment 22, an oxygen gas flow rate is preferably 400 sccm, an annealing temperature is preferably 250° C., a treatment time is preferably 3 minutes or more and 10 minutes or less. The treatment time is more preferably 3 minutes or more and 4 minutes or less. After that, through the formation of the SiN protective insulating film 9, the TFT is formed. The SiN protective insulating film 9 is preferably an SiN film formed at a temperature of 320° C. made from monosilane and ammonia as raw materials. Next, a contact hole is provided at a source electrode portion. Finally, in a case of a transmissive liquid crystal display device, a transparent electrode formed of indium tin oxide or the like is formed in a pixel portion, or in a case of a reflective liquid crystal display device, a reflective electrode formed of aluminum or the like is formed in the pixel portion. After that, the source electrode is connected to the pixel portion through the contact hole, to thereby form the TFT array.

In the oxygen plasma treatment 22, oxygen atoms are adsorbed onto the surface of the a-Si film 4. The oxygen atoms adsorbed onto the surface of the a-Si film 4 which is exposed between the source electrode 7 and the drain electrode 8 are introduced into the SiN protective insulating film 9 during the formation thereof, to thereby be bonded to silicon atoms in the SiN protective insulating film 9. FIG. 11 shows a result of secondary ion mass spectrometry for a laminated structure formed of the insulating film 3, the a-Si film 4, and the SiN protective insulating film 9 included in the TFT array manufactured by the above-mentioned manufacturing method. In FIG. 11, the ordinate axis shows an secondary ion intensity, and the abscissa axis shows a depth from a surface of the SiN protective insulating film 9. The secondary ion intensity corresponds to an oxygen atom density, and thus the curve of FIG. 11 shows a depth distribution of the oxygen atom density. Because of the oxygen plasma treatment 22, an oxygen concentration becomes higher in the interface between the a-Si film 4 and the SiN protective insulating film 9, the interface being located at a depth of 0.5 μm. Further, the oxygen atom density becomes higher over about 60 nm in the SiN protective insulating film 9 in the vicinity of the interface between the a-Si film 4 and the SiN protective insulating film 9. Specifically, the oxygen atoms adsorbed onto the surface of the a-Si film 4 during the formation of the SiN protective insulating film 9 are introduced in the SiN protective insulating film 9, and the oxygen atom density in the SiN protective insulating film 9 becomes higher in the vicinity of the portion contacting with the a-Si film 4 than other portions.

In a case where the silicon atom bonded to the oxygen atom and a nitrogen atom has a dangling bond, the dangling bond forms a level within a band gap of the SiN protective insulating film 9. The level becomes electrically neutral when electrons are captured, and becomes positively charged when the electrons are released. When the electrons captured in the level are released by accepting light energy, the level becomes positively charged. In a case where the level exists in the vicinity of the interface between the a-Si film 4 and the SiN protective insulating film 9, the level becomes a recombination center of photocarriers, which decreases the photo leakage current. However, in a case where a large number of levels are present in the SiN protective insulating film 9, positive charges are generated by light irradiation, which causes the photo leakage current.

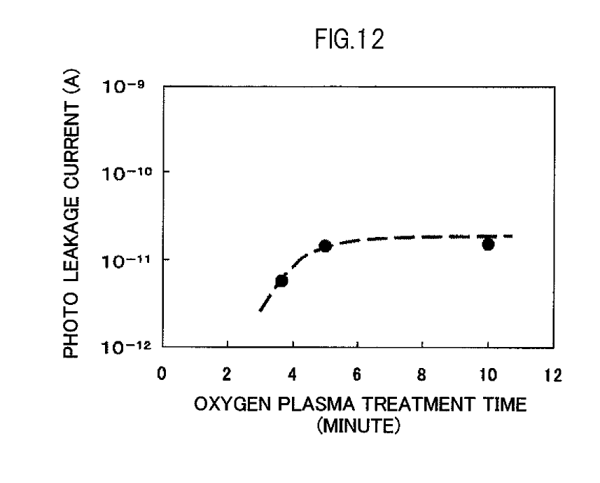

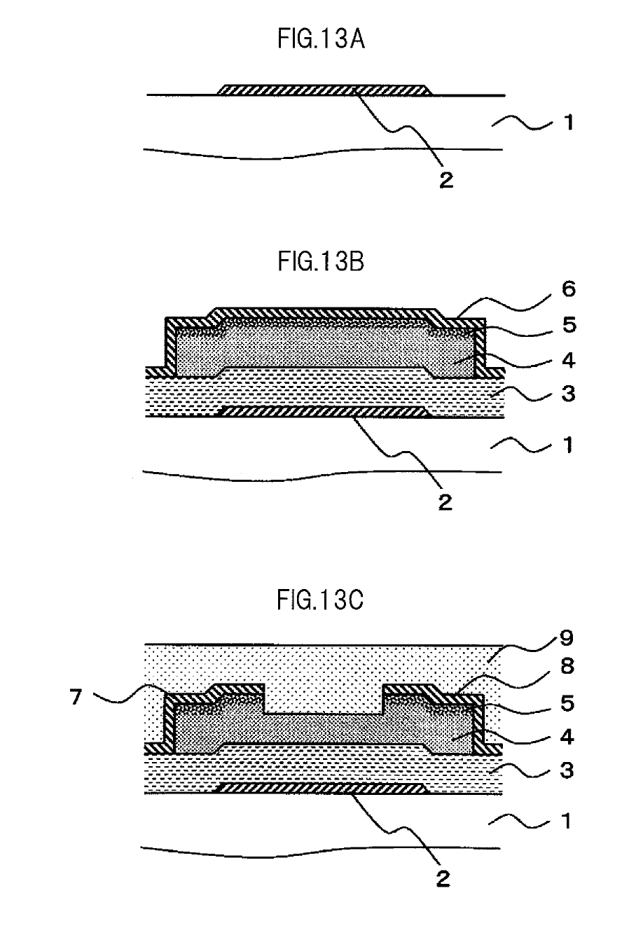

FIG. 12 shows a relation between the above-mentioned oxygen plasma treatment time and the photo leakage current. When the oxygen plasma treatment time is set to 4 minutes or less, the photo leakage current is suppressed to 1×10⁻¹¹ A or less, which reveals that excellent transistor characteristics are obtained.

Image deterioration of the liquid crystal display device can be prevented by suppressing the photo leakage current, whereby the present invention can be applied to a highly-bright liquid crystal display.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising a thin film transistor as a switching element,
the thin film transistor comprising:
a gate electrode covering a part of a surface of an insulating substrate;
an insulating film;
an amorphous silicon film;
a drain electrode and a source electrode; and
a protective insulating film,
the insulating film, the amorphous silicon film, the drain electrode and the source electrode, and the protective insulating film being laminated on the gate electrode in the stated order,
wherein the protective insulating film contains a defect which becomes a positive fixed charge under light irradiation.

2. A display device according to claim 1, wherein the amorphous silicon film and the protective insulating film are brought into contact with each other in a region between the drain electrode and the source electrode.

3. A display device according to claim 1, wherein the protective insulating film comprises silicon nitride.

4. A display device according to claim 1, wherein the positive fixed charge is induced in the protective insulating film when the protective insulating film is irradiated with white light having a continuous spectrum with a range from 400 nm to 800 nm.

5. A display device according to claim 1, wherein the protective insulating film comprises two types of defects having energy levels different from each other by 0.65 eV.

6. A display device according to claim 5, wherein:
a defect having a higher energy level between the two types of defects becomes a positive fixed charge under the light irradiation; and
the defect having the higher energy level becomes electrically neutral when an electron is captured, becomes positively charged when an electrons is released, and becomes the positive fixed charge under the light irradiation by releasing the electron captured by the defect having the higher energy level through photoexcitation.

7. A display device according to claim 1, wherein a surface density of the defects which become the positive fixed charges under the light irradiation is in a range from 2.5×10¹⁰ cm⁻² or more to 4.0×10¹⁰ cm⁻² or less.

8. A display device according to claim 2, wherein the protective insulating film has a higher oxygen atom density in a vicinity of a portion thereof contacting with the amorphous silicon film than oxygen atom densities in other portions.
